(19) United States
(12) Patent Application Publication
(10) Pub. No.: US 2021/0111310 A1
(43) Pub. Date: Apr. 15, 2021

(54) LIGHT EMITTING CHIP AND ASSOCIATED PACKAGE STRUCTURE

(71) Applicant: OPTO TECH CORPORATION, Hsinchu (TW)

(72) Inventors: Chang-Da TSAI, Kaohsiung City (TW); Wei-Che WU, Hsinchu County (TW); Kuan-Kai HUANG, Hsinchu City (TW)

(21) Appl. No.: 17/106,990

(22) Filed: Nov. 30, 2020

Related U.S. Application Data
(63) Continuation-in-part of application No. 16/221,891, filed on Dec. 17, 2018.

(30) Foreign Application Priority Data
May 18, 2018 (TW) 107117042

(51) Int. Cl. H01L 33/38; H01L 25/075; H01L 33/06; H01L 33/12; H01L 33/24; H01L 33/42; H01L 33/60; H01L 33/62; H01L 33/00

(52) U.S. Cl. CPC H01L 33/38; H01L 25/0753; H01L 33/06; H01L 33/12; H01L 33/24; H01L 2933/0016; H01L 33/60; H01L 33/62; H01L 33/007; H01L 33/0095; H01L 33/42

(57) ABSTRACT

A light emitting chip and associated package structure are provided. The light emitting chip includes a substrate, a first type layer, an active layer, a second type layer, a first type electrode and a second type electrode. A second portion of the first type layer is located over the substrate. A first portion of the first type layer is located over the second portion of the first type layer. The active layer is located over the first portion of the first type layer. The second type layer is located over the active layer. The first type electrode is contacted with a top surface and a sidewall of the second portion of the first type layer and contacted with a portion of a sidewall of the substrate. The second type electrode is contacted with the second type layer.

This is a continuation-in-part application of co-pending U.S. application Ser. No. 16/221,891, filed Dec. 17, 2018, which claims the benefit of Taiwan Patent Application No. 107117042, filed May 18, 2018, the subject matter of which is incorporated herein by reference.

### FIELD OF THE INVENTION

The present invention relates to a light emitting device and a package structure, and more particularly to a light emitting chip with a lateral electrode and a package structure with the light emitting chip.

### BACKGROUND OF THE INVENTION

As known, the nitride-based lighting device uses a sapphire substrate or a silicon carbide (SiC) substrate to emit blue light or green light. The silicon carbide substrate is electrically conductive, but the cost of the silicon carbide substrate is high. Since the cost of the sapphire substrate is lower, most of the nitride-based light emitting diodes are constructed on the sapphire substrates. However, the sapphire substrate is not electrically conductive. According to the conventional technologies, a portion of an epitaxial layer is etched to expose an N-type semiconductor layer, and the PN electrode is formed on the same side of the epitaxial layer to result in electric connection.

FIG. 1A is a schematic cross-sectional view illustrating a conventional light emitting chip that is constructed on a silicon carbide substrate. FIG. 1B is a schematic cross-sectional view illustrating a package structure with the light emitting chip of FIG. 1A. From bottom to top, the light emitting chip 100 comprises a first electrode 154, a silicon carbide substrate 110, an N-type layer 120, an active layer 130, a P-type layer 140 and a second electrode 152. Since the silicon carbide substrate 110 is electrically conductive, the first electrode 154 can be directly formed on a bottom surface of the silicon carbide substrate 110.

Generally, the structure of the nitride-based light emitting chip as shown in FIG. 1A may be slightly modified. For example, a buffer layer is additionally arranged between the silicon carbide substrate 110 and the N-type layer 120. The second electrode 152 is a stack structure comprising a transparent electrode layer and a metal electrode layer. For example, the transparent electrode layer is made of indium tin oxide (ITO). The active layer 130 has a double heterostructure or a quantum well structure. The materials of various layers and electrodes of the light emitting chip 100 are well known to those skilled in the art, and are not redundantly described herein.

In the package structure as shown in FIG. 1B, the light emitting chip 100 is fixed on a lead frame. The lead frame comprises a first conducting element 184 and a second conducting element 182. The first conducting element 184 comprises a platform for supporting the light emitting chip 100. The first electrode 154 is adhered on the first conducting element 184 through a conductive adhesive 188. For example, the conductive adhesive 188 is silver paste or aluminum paste.

Moreover, the second electrode 152 and the second conducting element 182 are connected with each other through a wire 186 according to a wire bonding process. Then, the light emitting chip 100 is encapsulated by a non-conductive material 190, wherein only the first conducting element 184 and the second conducting element 182 are exposed outside. Meanwhile, the package structure is formed. For example, the non-conductive material 190 is resin or silicone.

As mentioned above, the silicon carbide substrate 110 of the light emitting chip 100 is electrically conductive. Consequently, after the first electrode 154 of the light emitting chip 100 is adhered on the first conducting element 184 through the conductive adhesive 188, the electric connection between the first electrode 154 and the first conducting element 184 is established and the electric connection between the second electrode 152 and the second conducting element 182 is established through the wire 186.

In addition to package structure as shown in FIG. 1B, the light emitting chip 100 may be packaged according to the other packaging process. For example, the package structure is a surface mount device (SMD) package structure or a high power package structure.

FIG. 2A is a schematic cross-sectional view illustrating a conventional light emitting chip that is constructed on a sapphire substrate. FIG. 2B is a schematic top view illustrating the light emitting chip of FIG. 2A. FIG. 2C is a schematic cross-sectional view illustrating a package structure with the light emitting chip of FIG. 2A.

As shown in FIG. 2A, the light emitting chip 200 comprises a sapphire substrate 210, an N-type layer 220, an active layer 230, a P-type layer 240, an N-type electrode 254 and a P-type electrode 252.

As mentioned above, the sapphire substrate 210 is not electrically conductive. A mesa structure 235 is formed according to a mesa etching process, and thus the N-type layer 220 is exposed. As shown in FIG. 2A, the mesa structure 235 comprises the P-type layer 240, the active layer 230 and a first portion 220a of the N-type layer 220. Since a second portion 220b of the N-type layer 220 is not etched, the un-etched surface of the second portion 220b of the N-type layer 220 is exposed.

In other words, the N-type layer 220 is divided into the first portion 220a and the second portion 220b after the mesa etching process is completed. The first portion 220a of the N-type layer 220 belongs to the mesa structure 235. The second portion 220b of the N-type layer 220 does not belong to the mesa structure 235. The cross section area of the second portion 220b is larger than the cross section area of the first portion 220a. Consequently, the surface of the second portion 220b of the N-type layer 220 that is not covered by the mesa structure 235 is exposed outside.

After the mesa etching process is completed, the N-type electrode 254 is contacted with the exposed surface of the N-type layer 220, and the P-type electrode 252 is contacted with the P-type layer 240. The P-type electrode 252 is a stack structure comprising a transparent electrode layer and a metal electrode layer. For example, the transparent electrode layer is made of indium tin oxide (ITO).

That is, after the mesa etching process is completed, the cross section area of the active layer 230 is smaller than the cross section area of the sapphire substrate 210. The cross section area of the active layer 230 influences the luminance of the light emitting chip 200. For reducing the influence on the subsequent wire bonding process, the P-type electrode 252 and the N-type electrode 254 are circular electrodes. The diameters of the P-type electrode 252 and the N-type electrode 254 are in the range between 60 μm and 100 μm. Obviously, if the cross section area of the light emitting chip 200 is reduced, the light-output area of the light emitting chip 200 is reduced and the luminance of the light emitting chip 200 is abruptly decreased.

In FIG. 2B, the top view of the light emitting chip 200 is shown. The cross-sectional view of the light emitting chip 200 of FIG. 2B taken along the line a1-a2 is the light emitting chip 200 of FIG. 2A.

When a current flows through the light emitting chip 200 and the light emitting chip 200 illuminates, the current flows from the P-type electrode 252 to the N-type electrode 254. Since the structures of the P-type electrode 252 and the N-type electrode 254 of the light emitting chip 200 are asymmetrically arranged, the current density is not uniform. Under this circumstance, the light emitting chip 200 cannot produce the optimized luminous efficiency.

In the package structure as shown in FIG. 2C, the light emitting chip 200 is fixed on a lead frame. The lead frame comprises a first conducting element 284 and a second conducting element 282. The first conducting element 284 comprises a platform for supporting the light emitting chip 200. The sapphire substrate 210 of the light emitting chip 200 is adhered on the platform of the first conducting element 284 through a fixing adhesive 288 (e.g., a silicone adhesive). Moreover, the N-type electrode 254 and the first conducting element 284 are connected with each other through a first wire 285 according to a wire bonding process, and the P-type electrode 252 and the second conducting element 282 are connected with each other through a second wire 286 according to the wire bonding process. Then, the light emitting chip 200 is encapsulated by a non-conductive material 190 (e.g., resin or silicone), wherein only the first conducting element 284 and the second conducting element 282 are exposed outside. Meanwhile, the package structure is formed.

In addition to the package structure as shown in FIG. 2C, the light emitting chip 200 may be packaged according to the other packaging process. For example, the package structure is a surface mount device (SMD) package structure or a high power package structure.

As mentioned above, the sapphire substrate 210 of the light emitting chip 200 is not electrically conductive. Consequently, after the sapphire substrate 210 of the light emitting chip 200 is adhered on the first conducting element 284 through the fixing adhesive 288, the sapphire substrate 210 is not electrically connected with the first conducting element 284. Consequently, the wire bonding process is performed twice. That is, the N-type electrode 254 and the first conducting element 284 are connected with each other through the first wire 285 according to the wire bonding process, and the P-type electrode 252 and the second conducting element 282 are connected with each other through the second wire 286 according to the wire bonding process.

### SUMMARY OF THE INVENTION

An embodiment of the present invention provides a light emitting chip. The light emitting chip includes a substrate, a first type layer, an active layer, a second type layer, a first type electrode and a second type electrode. The first type layer includes a first portion and a second portion. The second portion of the first type layer is located over the substrate. The first portion of the first type layer is located over the second portion of the first type layer. The active layer is located over the first portion of the first type layer. The second type layer is located over the active layer. The first type electrode is contacted with a sidewall of the second portion of the first type layer and contacted with a sidewall of the substrate. The second type electrode is located over the second type layer. A mesa structure is formed by the second type layer, the active layer and the first portion of the first type layer collaboratively.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic cross-sectional view illustrating a conventional light emitting chip that is constructed on a silicon carbide substrate;

FIG. 1B (prior art) is a schematic cross-sectional view illustrating a package structure with the light emitting chip of FIG. 1A;

FIG. 2A (prior art) is a schematic cross-sectional view illustrating a conventional light emitting chip that is constructed on a sapphire substrate;

FIG. 2B (prior art) is a schematic top view illustrating the light emitting chip of FIG. 2A;

FIG. 2C (prior art) is a schematic cross-sectional view illustrating a package structure with the light emitting chip of FIG. 2A;

FIG. 3A is a schematic cross-sectional view illustrating a light emitting chip according to an embodiment of the present invention;

FIG. 3B is a schematic top view illustrating an example of the light emitting chip of FIG. 3A and taken along a viewpoint;

FIG. 3C is a schematic top view illustrating another example of the light emitting chip of FIG. 3A and taken along another viewpoint;

FIG. 3D is a schematic cross-sectional view illustrating a package structure with the light emitting chip of FIG. 3A;

FIGS. 4A to 4G schematically illustrate a flowchart of a manufacturing method of the light emitting chip according to the embodiment of the present invention;

FIG. 5A is a top view illustrating a variant example of the mesa structure of the light emitting chip;

FIG. 5B is a top view illustrating another variant example of the mesa structure of the light emitting chip; and

FIG. 6 is a schematic perspective view illustrating a SMD package structure with plural light emitting chips.

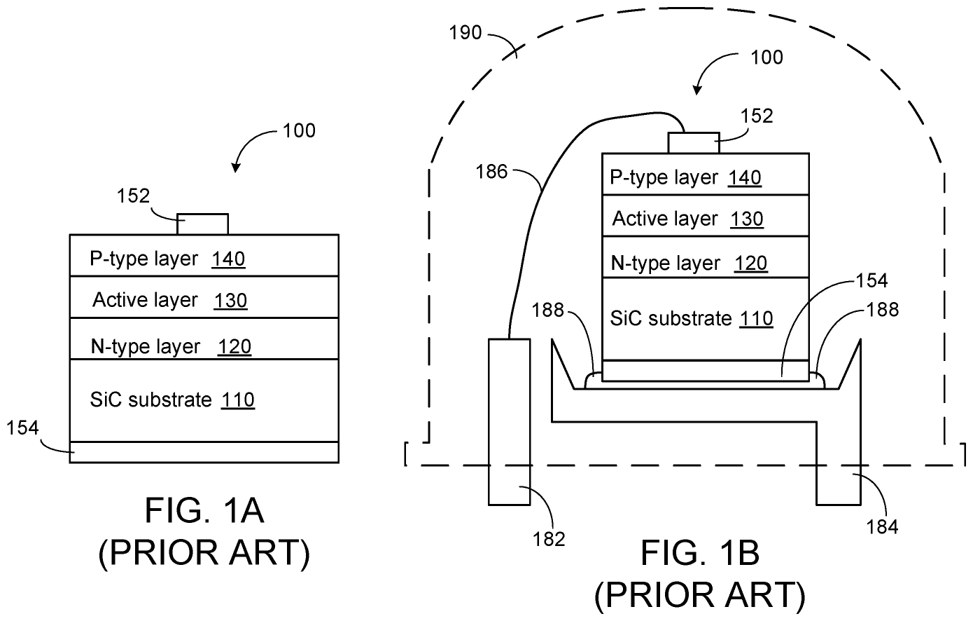

### DETAILED DESCRIPTION OF PREFERRED EMBODIMENTS

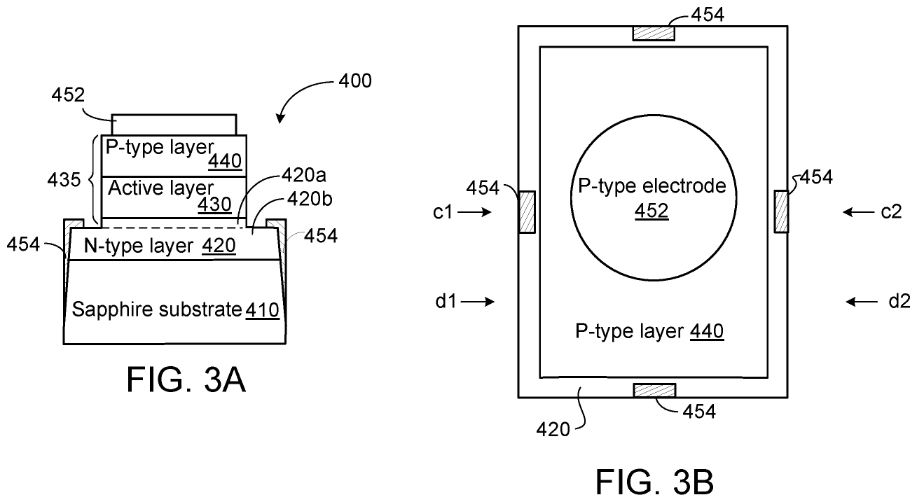

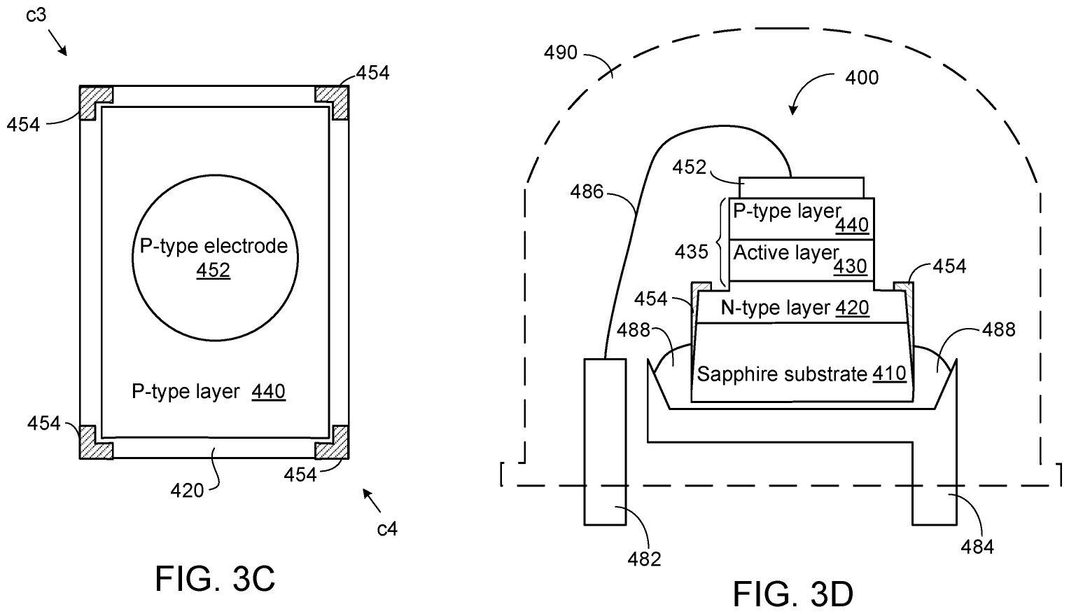

FIG. 3A is a schematic cross-sectional view illustrating a light emitting chip according to an embodiment of the present invention. FIG. 3B is a schematic top view illustrating an example of the light emitting chip of FIG. 3A and taken along a viewpoint. FIG. 3C is a schematic top view illustrating another example of the light emitting chip of FIG. 3A and taken along another viewpoint. FIG. 3D is a schematic cross-sectional view illustrating a package structure with the light emitting chip of FIG. 3A.

As shown in FIG. 3A, the light emitting chip 400 comprises a sapphire substrate 410, an N-type layer 420, an N-type electrode 454, an active layer 430, a P-type layer 440 and a P-type electrode 452. In this embodiment, the N-type electrode 454 is formed on a sidewall of the light emitting chip 400 and contacted with the N-type layer 420 and the sapphire substrate 410. A mesa structure 435 is formed according to a mesa etching process. The light emitting chip 400, the package structure and the manufacturing method will be described in more details as follows.

As shown in FIG. 3A, the mesa structure 435 comprises the P-type layer 440, the active layer 430 and a first portion 420a of the N-type layer 420. Since a second portion 420b of the N-type layer 420 is not etched, the un-etched surface of the second portion 420b of the N-type layer 420 is exposed.

In other words, the N-type layer 420 is divided into the first portion 420a and the second portion 420b after the mesa etching process is completed. The first portion 420a of the N-type layer 420 belongs to the mesa structure 435. The second portion 420b of the N-type layer 420 does not belong to the mesa structure 435. The cross section area of the second portion 420b is larger than the cross section area of the first portion 420a. Consequently, the surface of the second portion 420b of the N-type layer 420 that is not covered by the mesa structure 435 is exposed outside.

After the mesa etching process is completed, the P-type electrode 452 is only formed directly above the P-type layer 440 and the P-type electrode 452 is contacted with the P-type layer 440. Furthermore, the N-type electrode 454 is formed on the sidewall of the light emitting chip 400 and contacted with the N-type layer 420 and the sapphire substrate 410.

In this embodiment, the N-type electrode 454 is contacted with the sidewall and the top surface of the second portion 420b of the N-type layer 420. The P-type electrode 452 is a stack structure comprising a transparent electrode layer and a metal electrode layer. For example, the transparent electrode layer is made of indium tin oxide (ITO).

Generally, the structure of the nitride-based light emitting chip as shown in FIG. 3A may be slightly modified. For example, a buffer layer is additionally arranged between the sapphire substrate 410 and the N-type layer 420. The active layer 430 can emit blue light or green light. The active layer 430 has a double heterostructure or a quantum well structure. The materials of various layers and electrodes of the light emitting chip 300 are well known to those skilled in the art, and are not redundantly described herein.

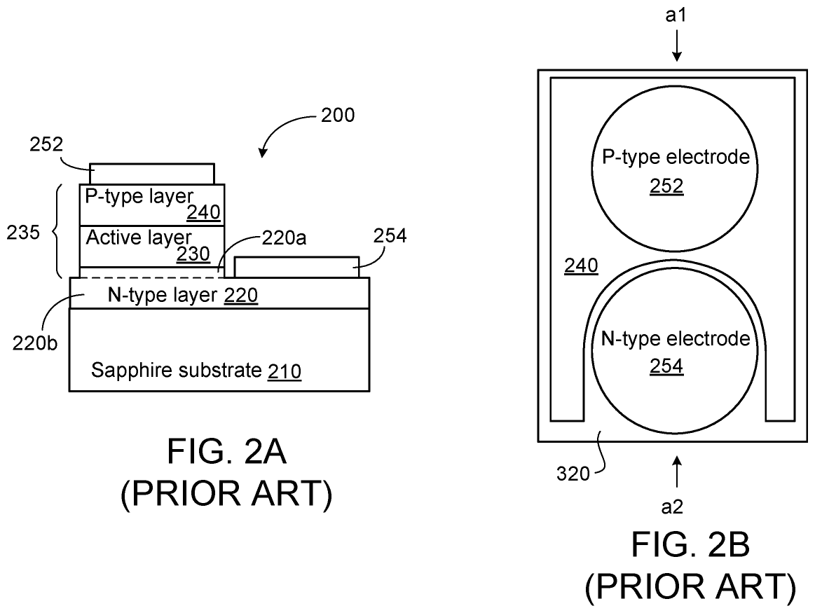

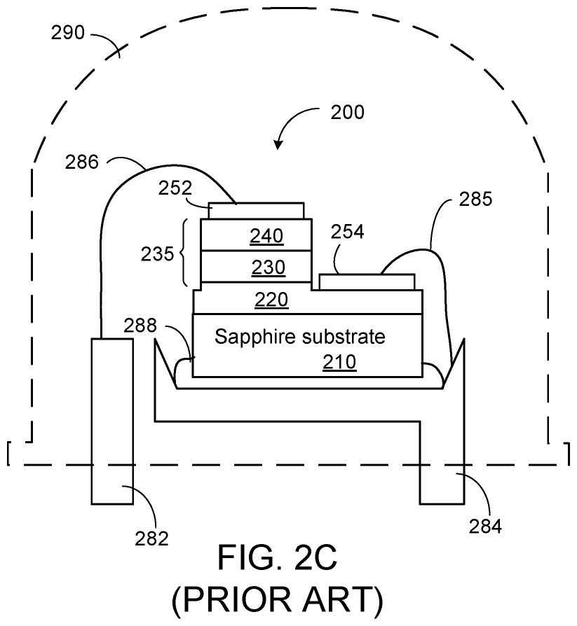

As mentioned above, the N-type electrode 454 is formed on the sidewall and the top surface of the second portion 420b of the N-type layer 420. Since the wire boning process is not required to connect the N-type electrode 454 in the subsequent packaging process, the size of the N-type electrode 454 is reduced. That is, it is not necessary to retain an exposed surface of the N-type layer 420 (e.g., with a diameter in the range between 60 μm and 100 μm) to form the N-type electrode. In comparison with the light emitting chip 200 of FIG. 2A, the active layer 430 of the light emitting chip 400 has a larger area. Consequently, the luminance of the light emitting chip 400 is effectively enhanced.

More especially, the N-type electrode 454 may be located at any position of a sidewall of the light emitting chip 400. In FIG. 3B, the top view of an example of the light emitting chip 400 is shown. In this embodiment, the N-type electrodes 454 are distributed to four sidewalls of the square-shaped light emitting chip 400. The cross-sectional view of the light emitting chip 400 of FIG. 3B taken along the line c1-c2 is the light emitting chip 400 of FIG. 3A.

According to the present invention, the N-type electrode 454 is contacted with a portion of the sidewall of the sapphire substrate 410. For example, the cross-sectional view of the light emitting chip 400 of FIG. 3B taken along the line d1-d2 will show that the N-type electrode 454 is not contacted with the sapphire substrate 410.

In FIG. 3C, the top view of another example of the light emitting chip 400 is shown. In this embodiment, the N-type electrodes 454 are distributed to four corners of the square-shaped light emitting chip 400. The cross-sectional view of the light emitting chip 400 of FIG. 3C taken along the line c3-c4 is the light emitting chip 400 of FIG. 3A.

In the above embodiments, the light emitting chip 400 comprises four N-type electrodes 454. It is noted that the number of the N-type electrodes 454 is not restricted. In case that the light emitting chip 400 comprises at least one N-type electrode 454, the light emitting chip 400 can illuminate the surroundings. In the light emitting chip 400 of FIG. 3A, the N-type electrode 454 is contacted with the sidewall and the top surface of the second portion 420b of the N-type layer 420 and the sidewall of the sapphire substrate 410. The structure of the N-type electrode may be modified as long as the N-type electrode 454 is contacted with the sidewall of the second portion 420b of the N-type layer 420 and the sidewall of the sapphire substrate 410.

In the package structure as shown in FIG. 3D, the light emitting chip 400 is fixed on a lead frame. The lead frame comprises a first conducting element 484 and a second conducting element 482. The first conducting element 484 comprises a platform for supporting the light emitting chip 400. The sapphire substrate 410 of the light emitting chip 400 is adhered on the platform of the first conducting element 484 through a conductive adhesive 488 (e.g., silver paste or aluminum paste). Since the N-type electrode 454 is formed on the sidewall of the light emitting chip 400 and extended to the sidewall of the sapphire substrate 410, the electric connection between the N-type electrode 454 and the first conducting element 484 is established through the conductive adhesive 488. Moreover, the P-type electrode 452 and the second conducting element 482 are connected with each other through a wire 486 according to a wire bonding process. Then, the light emitting chip 400 is encapsulated by a non-conductive material 490 (e.g., resin or silicone), wherein only the first conducting element 484 and the second conducting element 482 are exposed outside. Meanwhile, the package structure is formed.

As mentioned above, the sapphire substrate 410 is not electrically conductive. The electric connection between the N-type electrode 454 and the first conducting element 484 is established through the conductive adhesive 488. Consequently, only one wire bonding process is required to establish the electric connection between the P-type electrode 452 and the second conducting element 482.

In addition to the package structure as shown in FIG. 3D, the light emitting chip 400 may be packaged according to the other packaging process. For example, the package structure is a surface mount device (SMD) package structure or a high power package structure.

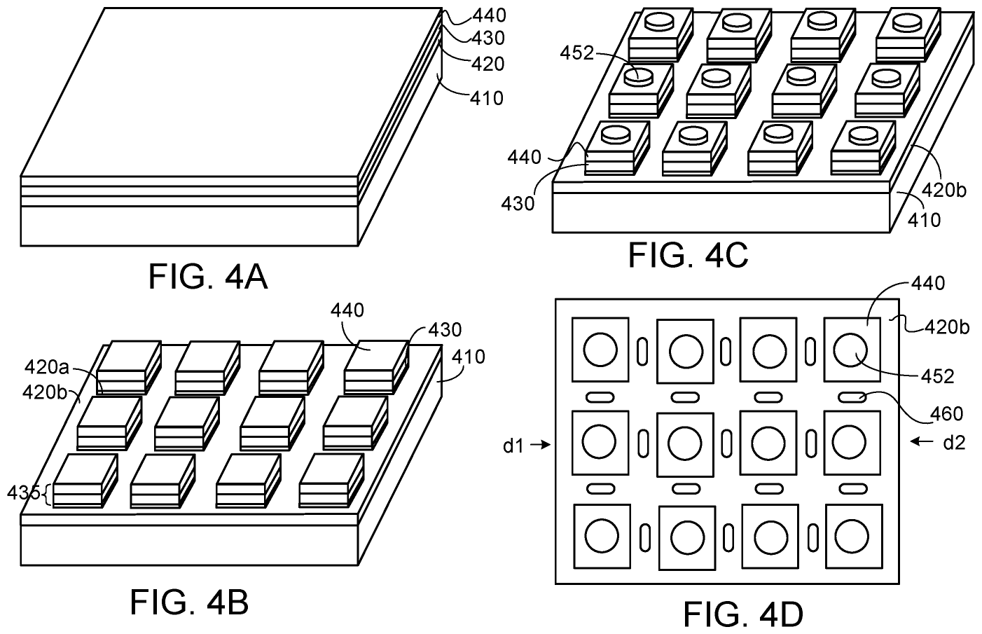

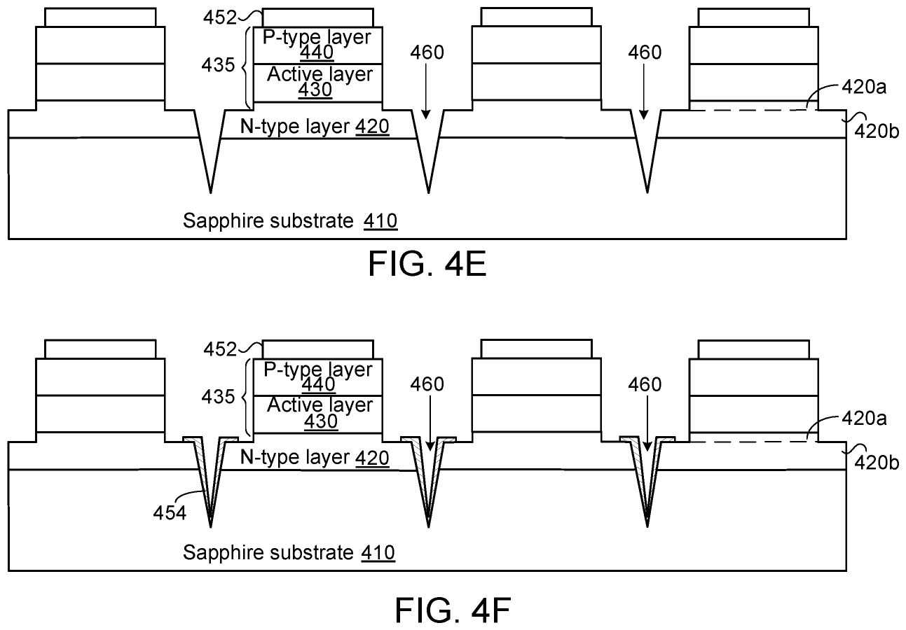

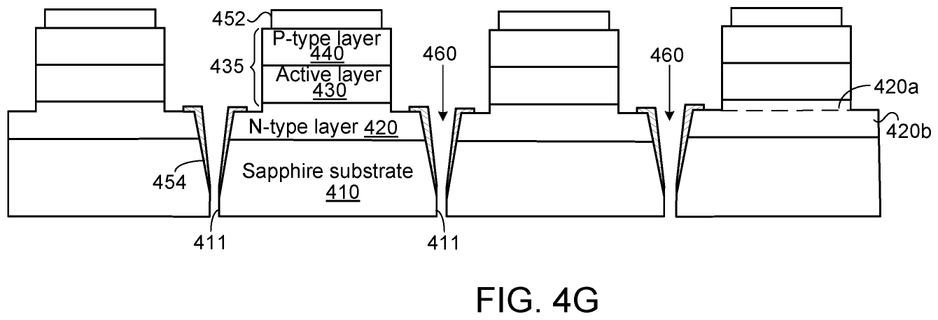

FIGS. 4A to 4G schematically illustrate a flowchart of a manufacturing method of the light emitting chip according to the embodiment of the present invention.

Please refer to FIG. 4A. Firstly, an epitaxial wafer is provided. The wafer comprises a non-conductive sapphire substrate 410, an N-type layer 420, an active layer 430 and a P-type layer 440. The N-type layer 420 is located over the sapphire substrate 410. The active layer 430 is located over the N-type layer 420. The P-type layer 440 is located over the active layer 430.

Then, as shown in FIG. 4B, a mesa etching process is performed. That is, plural mesa areas are defined in the wafer. After the P-type layer 440, the active layer 430 and a part of the N-type layer 420 excluding the mesa areas are removed, the N-type layer 420 is partially exposed and plural mesa structures 435 are formed. That is, after the mesa etching process is completed, the un-etched surface of a second portion 420b of the N-type layer 420 is exposed.

Please refer to FIG. 4C. A P-type electrode 452 is formed on the P-type layers 440 of the mesa structures 435. The P-type electrode 452 is a stack structure comprising a transparent electrode layer and a metal electrode layer. For example, the transparent electrode layer is made of indium tin oxide (ITO). It is noted that the timing of forming the P-type electrode 452 is not restricted. In another embodiment, after the mesa etching process is completed, an N-type electrode 454 is firstly formed and then the P-type electrode 452 is formed.

Please refer to FIG. 4D. Then, an etching process is performed to form plural discontinuous trench structures 460 around the plural mesa structures 435. For example, the etching process is a laser etching process, a dry etching process or a wet etching process. For example, in case that the laser etching process is adopted, the energy of the laser beam is controlled. Consequently, the sapphire substrate 410 is not completely cut, but the V-shaped trench structures 460 are formed.

FIG. 4E is a schematic cross-sectional view illustrating the structure of FIG. 4D and taken along the line d1-d2. After the etching process is completed, the plural discontinuous V-shaped trench structures 460 are formed between the plural mesa structures 435. Moreover, the second portion 420b of the N-type layer 420 and the sapphire substrate 410 are exposed to the sidewall of the corresponding trench structures 460.

Please refer to FIG. 4F. The N-type electrode 454 is formed on the sidewall of the corresponding trench structure 460 and the surface of the second portion 420b of the N-type layer 420 outside the trench structure 460. That is, the N-type electrode 454 is contacted with a portion of the sidewall of the sapphire substrate 410 and is contacted with the sidewall and the top surface of the second portion 420b of the N-type layer 420. In case that the thickness of the N-type electrode 454 is insufficient, an electroplating process is selectively used to increase the thickness of the N-type electrode 454.

Afterwards, the bottom surface of the sapphire substrate 410 is polished, so that the sapphire substrate 410 is thinned. Then, a laser backside cutting process is performed and a stress is provided to separate the above structure. As shown in FIG. 4G, plural light emitting chips are formed. The N-type electrodes 454 of the light emitting chips are formed on the sidewalls of the light emitting chips.

According to the embodiment of the invention, the N-type electrode 454 does not cover on the whole sidewall of the sapphire substrate 410 after the laser backside cutting process. As shown in FIG. 4G, the sidewall of the sapphire structure 410 of each light emitting chip includes fracture surface 411 after separating the light emitting chips. The N-type electrode 454 does not contact with the fracture surface 411 of the sapphire substrate 410.

That is to say, the N-type electrode 454 is contacted with the top surface and the sidewall of second portion 420b of the N-type layer 420. Also, the N-type electrode 454 is extended to contact with the upper portion of the sidewall of the sapphire substrate 410. Obviously, the N-type electrodes 454 does not cover with the lower portion (i.e., fracture surface 411) of the sapphire substrate 410.

For increasing the luminance of the light emitting chip, the manufacturing method may be further modified. For example, before the light emitting chips are separated, a reflecting layer is formed on the backside of the sapphire substrates 410. Then, a laser backside cutting process is performed and a stress is provided to separate the above structure. Consequently, plural light emitting chips are formed. Since the bottom surface of the sapphire substrates 410 of each light emitting chip is equipped with the reflecting layer to reflect the light beam from the active layer, the luminance of the light emitting chip is increased. An example of the reflecting layer includes but is not limited to a distributed Bragg reflecting layer (DBR layer) or an omni-directional reflecting layer (ODR layer).

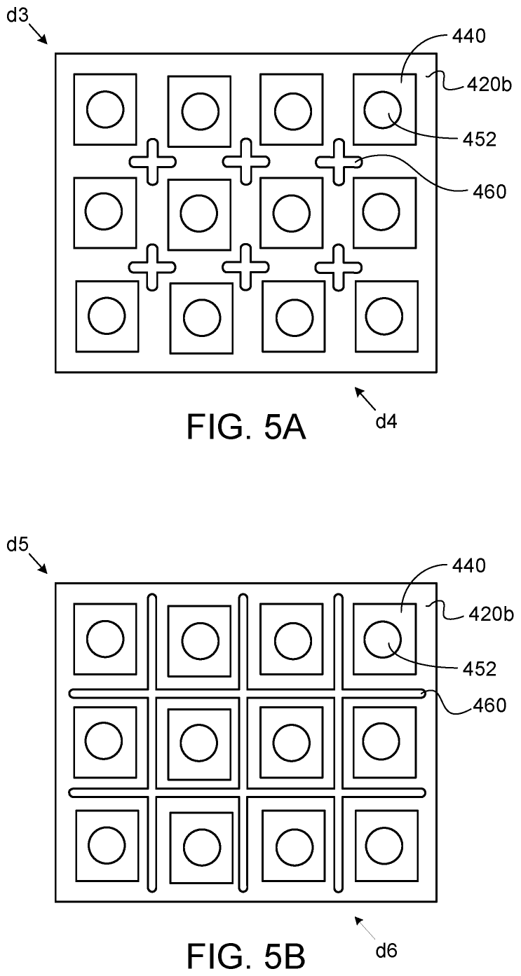

FIG. 5A is a top view illustrating a variant example of the mesa structure of the light emitting chip. As shown in FIG. 5A, plural cross-shaped trench structures 460 are located at the corners of the mesa structures 435. The cross-sectional view of the light emitting chip of FIG. 5A taken along the line d3-d4 is also the light emitting chip of FIG. 4E. Then, the N-type electrode 454 is formed on the sidewall of the corresponding trench structure 460 and the top surface of the second portion 420b of the N-type layer 420 outside the trench structure 460. After the sapphire substrates 410 are separated, plural light emitting chips are formed. Under this circumstance, the N-type electrodes 454 of the light emitting chips are formed on the corners of the light emitting chips.

FIG. 5B is a top view illustrating another variant example of the mesa structure of the light emitting chip. As shown in FIG. 5B, plural elongated trench structures 460 are formed in sidewalls of the mesa structures 435. The cross-sectional view of the light emitting chip of FIG. 5B taken along the line d5-d6 is also the light emitting chip of FIG. 4E. Then, the N-type electrode 454 is formed on the sidewall of the corresponding trench structure 460 and the top surface of the second portion 420b of the N-type layer 420 outside the trench structure 460. After the sapphire substrates 410 are separated, plural light emitting chips are formed. Under this circumstance, the N-type electrodes 454 of the light emitting chips are formed on the sidewalls of the light emitting chips. It is noted that numerous modifications and alterations may be made while retaining the teachings of the invention. In an embodiment, the trench structures 460 are completely covered by the N-type electrodes 454. Alternatively, the trench structures 460 are partially covered by the N-type electrodes 454 as long as the N-type electrodes 454 are contacted with the second portions 420b of the corresponding N-type layers 420.

From the above descriptions, the present invention provides a light emitting chip with a lateral electrode, a package structure with the light emitting chip and a manufacturing method of the light emitting chip. After the current flows into the P-type electrode 452, the current is uniformly spread into the N-type layer 420 and transferred to the N-type electrodes 454 at four sidewalls or four corners. Consequently, the current is effectively distributed, and the illuminating efficiency of the active layer 430 is enhanced. Moreover, since the sidewall of the light emitting chip is only partially covered by the N-type electrode 454, the light emitting chip can still emit the light beam through the sidewall of the light emitting chip. That is, the light output efficiency is increased. Even if the size of the light emitting chip is reduced, the light emitting chip still has a larger illuminating area.

In the above embodiment, the N-type layer is formed on the sapphire substrate, and the P-type layer is formed on the mesa structure. It is noted that numerous modifications and alterations may be made while retaining the teachings of the invention. For example, in another embodiment, the positions of the P-type layer and the N-type layer are exchanged. That is, the P-type layer is formed on the sapphire substrate, and the N-type layer is formed on the mesa structure. In addition, the N-type electrode is located over the mesa structure, and the P-type electrode is formed on the sidewall of the light emitting chip.

In accordance with the present invention, the N-type electrode 454 of the light emitting chip 400 is formed on the sidewall of the light emitting chip 400. For packaging the light emitting chip 400, the light emitting chip 400 is fixed on the first conducting element 484 through the conductive adhesive 488, and the electric connection between the N-type electrode 454 and the first conducting element 484 is established through the conductive adhesive 488. Consequently, only one wire bonding process is required to establish the electric connection between the P-type electrode 452 and the second conducting element 482. In comparison with the conventional technology of the light emitting chip having the sapphire substrate, one wire bonding process is omitted. Consequently, the packaging cost is reduced.

As mentioned above, only one wire bonding process is required to fabricate the light emitting chip 400 of FIG. 3A. In case that plural light emitting chips having the same structure are packaged together, the number of the wire bonding processes is reduced and the size of the package structure is reduced.

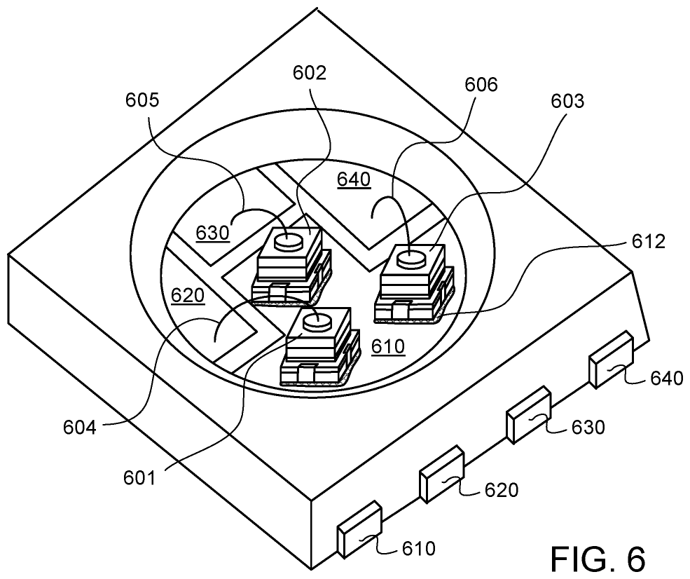

FIG. 6 is a schematic perspective view illustrating a SMD package structure with plural light emitting chips. The package structure comprises four conducting elements 610, 620, 630 and 640. Moreover, three light emitting chips 601, 602 and 603 are adhered on the first conducting element 610 through a conductive adhesive 612. Consequently, the N-type electrodes of the light emitting chips 601, 602 and 603 are electrically connected with the first conducting element 610.

Moreover, the P-type electrode of the light emitting chip 601 and the second conducting element 620 are connected with each other through a wire 604 according to the wire bonding process. The P-type electrode of the light emitting chip 602 and the third conducting element 630 are connected with each other through a wire 605 according to the wire bonding process. The P-type electrode of the light emitting chip 603 and the fourth conducting element 640 are connected with each other through a wire 606 according to the wire bonding process. Then, the light emitting chips 601, 602 and 603 are encapsulated by a non-conductive material (e.g., resin or silicone), wherein only the four conducting elements 610, 620, 630 and 640 are exposed outside. Meanwhile, the package structure is formed.

In FIG. 6, three light emitting chips 601, 602 and 603 with the same structure are packaged in the package structure. It is noted that the number of the light emitting chips in the package structure is not restricted. For example, the sapphire substrate of at least one light emitting chip is adhered on the first conducting element 610 to form the package structure.

In another embodiment, two light emitting chips as shown in FIG. 3A (e.g., a blue light emitting chip and a green light emitting chip) are attached on the first conducting element 610, and one light emitting chip (e.g., a red light emitting chip) with a different structure is attached on the first conducting element 610. Then, the three light emitting chips are respectively connected with the second conducting element 620, the third conducting element 630 and the fourth conducting element 640 according to the wire bonding process. Consequently, the SMD package structure with the blue light emitting chip, the green light emitting chip and the red light emitting chip is fabricated.

It is noted that the package structure of the present invention is not restricted to the package structure of FIG. 6. That is, the light emitting chips 601, 602 and 603 can be packaged into another package structure according to another packaging process. For example, a chip on board (COB) package structure is feasible.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light emitting chip, comprising:
a substrate;
a first type layer comprising a first portion and a second portion, wherein the second portion of the first type layer is located over the substrate, and the first portion of the first type layer is located over the second portion of the first type layer;
an active layer located over the first portion of the first type layer;
a second type layer located over the active layer;
a first type electrode contacted with a top surface and a sidewall of the second portion of the first type layer and contacted with a upper portion of a sidewall of the substrate; and
a second type electrode located over the second type layer,
wherein the sidewall of the substrate includes a fracture surface, the first type electrode is extended to contact with the upper portion of the sidewall of the substrate, and the first type electrode is not contacted with the fraction surface; and
wherein a mesa structure is formed by the second type layer, the active layer and the first portion of the first type layer collaboratively.

2. The light emitting chip as claimed in claim 1, wherein the second type electrode is only formed directly above the second type layer.

3. The light emitting chip as claimed in claim 1, wherein the light emitting chip further comprises a buffer layer, wherein the buffer layer is located over the substrate, and located under the first type layer.

4. The light emitting chip as claimed in claim 1, wherein the second electrode is a stack structure comprising a transparent electrode layer and a metal electrode layer.

5. The light emitting chip as claimed in claim 1, wherein the active layer has a double heterostructure or a quantum well structure.

6. The light emitting chip as claimed in claim 1, wherein the substrate is a sapphire substrate.

7. The light emitting chip as claimed in claim 1, wherein the first type layer is an N-type layer, the second type layer is a P-type layer, the first type electrode is an N-type electrode, and the second type electrode is a P-type electrode.

8. The light emitting chip as claimed in claim 1, wherein the first portion of the first type layer has a first cross section area, and the second portion of the first type layer has a second cross section area, wherein the second cross section area is larger than the first cross section area.

9. The light emitting chip as claimed in claim 1, wherein the light emitting chip further comprises a reflecting layer, and the reflecting layer is formed on a backside of the substrate.

10. The light emitting chip as claimed in claim 9, wherein the reflecting layer is a distributed Bragg reflecting layer or an omni-directional reflecting layer.

11. A package structure, comprising:
a first light emitting chip comprising a substrate, a first type layer with a first portion and a second portion, an active layer, a second type layer, a first type electrode and a second type electrode, wherein the second portion of the first type layer is located over the substrate, the first portion of the first type layer is located over the second portion of the first type layer, the active layer is located over the first portion of the first type layer, the second type layer is located over the active layer, the first type electrode is contacted with a top surface and a sidewall of the second portion of the first type layer and contacted with a upper portion of a sidewall of the substrate, the second type electrode is located over the second type layer, the sidewall of the substrate includes a fracture surface, the first type electrode is extended to contact with the upper portion of the sidewall of the substrate, the first type electrode is not contacted with the fraction surface, and a mesa structure is formed by the second type layer, the active layer and the first portion of the first type layer collaboratively;
a first conducting element comprising a platform, wherein a bottom surface of the substrate is adhered on the platform through a conductive adhesive, and the conductive adhesive is contacted with the first type electrode and the fraction surface, so that the first conducting element and the first type electrode are electrically connected with each other;
a second conducting element electrically connected with the second type electrode through a first wire; and
a non-conductive material for encapsulating the first light emitting chip.

12. The package structure as claimed in claim 11, further comprising:
a second light emitting chip comprising a substrate, a first type layer with a first portion and a second portion, an active layer, a second type layer, a first type electrode and a second type electrode, wherein the second portion of the first type layer is located over the substrate, the first portion of the first type layer is located over the second portion of the first type layer, the active layer located over the first portion of the first type layer, the second type layer is located over the active layer, the first type electrode is contacted with a sidewall of the second portion of the first type layer and contacted with a sidewall of the substrate, and the second type electrode is located over the second type layer, wherein a bottom surface of the substrate of the second light emitting chip is adhered on the platform of the first conducting element through the conductive adhesive, and the conductive adhesive is contacted with the first type electrode of the second light emitting chip, so that the first conducting element and the first type electrode of the second light emitting chip are electrically connected with each other; and
a third conducting element electrically connected with the second type electrode of the second light emitting chip through a second wire.

13. The package structure as claimed in claim 11, wherein the first light emitting chip further comprises a buffer layer, wherein the buffer layer is located over the substrate, and located under the first type layer.

14. The package structure as claimed in claim 11, wherein the second electrode is a stack structure comprising a transparent electrode layer and a metal electrode layer.

15. The package structure as claimed in claim 11, wherein the substrate is a sapphire substrate.

16. The package structure as claimed in claim 11, wherein the first type layer is an N-type layer, the second type layer is a P-type layer, the first type electrode is an N-type electrode, and the second type electrode is a P-type electrode.

17. The package structure as claimed in claim 11, wherein the conductive adhesive is silver paste or aluminum paste, and the non-conductive material is resin or silicone.

18. The package structure as claimed in claim 11, wherein the first portion of the first type layer has a first cross section area, and the second portion of the first type layer has a second cross section area, wherein the second cross section area is larger than the first cross section area.

19. The package structure as claimed in claim 11, wherein the first light emitting chip further comprises a reflecting layer, and the reflecting layer is formed on a backside of the substrate.

20. The package structure as claimed in claim 19, wherein the reflecting layer is a distributed Bragg reflecting layer or an omni-directional reflecting layer.
